(19) United States
(12) Patent Application Publication
(10) Pub. No.: US 2021/0111036 A1
(43) Pub. Date: Apr. 15, 2021

(54) MOUNTING METHOD OF WORK

(71) Applicant: LINTEC CORPORATION, Tokyo (JP)

(72) Inventor: Yoshiaki SUGISHITA, Tokyo (JP)

(73) Assignee: LINTEC CORPORATION, Tokyo (JP)

(21) Appl. No.: 17/130,608

(22) Filed: Dec. 22, 2020

Related U.S. Application Data
(63) Continuation of application No. PCT/JP2019/011770, filed on Mar. 20, 2019.

(30) Foreign Application Priority Data
Jun. 29, 2018 (JP) 2018-124792

(51) Int. Cl. H01L 21/48; H01L 21/78

(52) U.S. Cl. CPC H01L 21/4825; H01L 21/78

(57) ABSTRACT

A mounting method includes: a stacking step PC1 of stacking an adhesive layer AL containing swell grains SG that swell when predetermined energy HT is applied, on a projection-formed surface WF1 of a work WF, the projection-formed surface WF1 having projections BP formed thereon; a mounting step PC4 of bringing the projections BP into contact with a support LF to attach, to the support LF, the work WF on which the adhesive layer AL is stacked; and an energy applying step PC5 of applying the energy HT to the adhesive layer AL to swell the swell grains SG, thereby making contact regions of the adhesive layer AL with the support LF larger than before swelling the swell grains SG.

### BACKGROUND OF THE INVENTION

### Field of the Invention

The present invention relates to a mounting method of a work, and for example, relates to a method of mounting a work such as a semiconductor chip on a support.

### Description of the Related Art

Examples of a method of mounting a discrete piece on its support include a method of attaching a work having projections such as solder bumps, to a substrate which is its support. In some method, a chip with bumps that has a resin layer is bonded on a support mainly through the bumps. At this time, the resin layer is not positively bonded to the substrate.

### SUMMARY OF THE INVENTION

The present invention disclosed and claimed herein, in one aspect thereof, comprises a mounting method. The method comprises:

a stacking step of stacking an adhesive layer containing a swell grain that swells when predetermined energy is applied, on a projection-formed surface of a work, the projection-formed surface having a projection formed thereon;

a mounting step of bringing the projection into contact with a support to attach, to the support, the work on which the adhesive layer is stacked; and

an energy applying step of applying the energy to the adhesive layer to swell the swell grain, thereby making a contact region of the adhesive layer with the support larger than before swelling the swell grain.

Further scope of applicability of the present invention will become apparent from the detailed description given hereinafter. The detailed description and embodiments are only given as examples though showing preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings,

FIG. 1 is an explanatory view of a mounting method according to one embodiment.

### DETAILED DESCRIPTION

An embodiment will be hereinafter described based on the drawings.

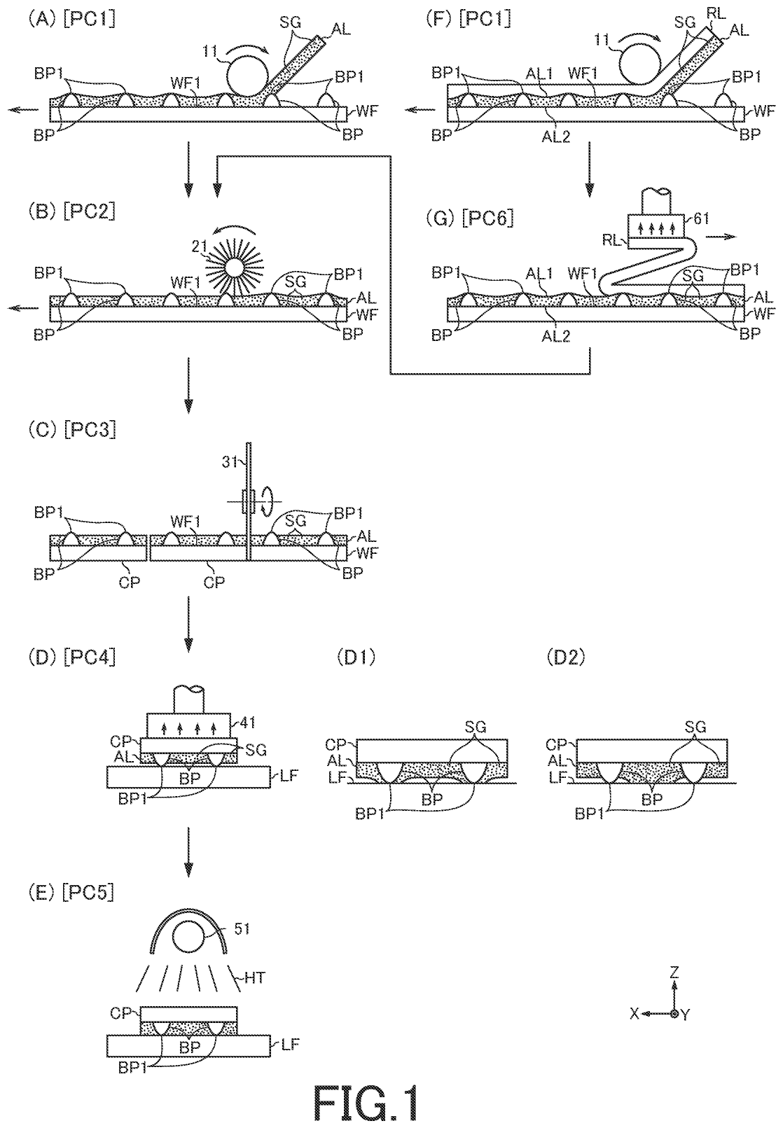

It should be noted that X-axis, Y-axis, and Z-axis in the embodiment are orthogonal to one another, where the X-axis and Y-axis are within a predetermined plane while the Z-axis is orthogonal to the predetermined plane. Further, in the embodiment, FIG. 1 as viewed from the near side in terms of the direction parallel to the Y-axis is used as a reference for direction, and when a direction is mentioned without any designation of a drawing, an “upper” direction means a direction indicated by an arrow along the Z-axis, a “lower” direction means a direction opposite the upper direction, a “left” direction means a direction indicated by an arrow along the X-axis, a “right” direction means a direction opposite the “left” direction, a “front” direction means a direction toward the near side in FIG. 1 in terms of a direction parallel to the Y-axis, and a “rear” direction means a direction opposite the “front” direction. FIG. 1 includes (A) to (F) parts, each of which illustrates a certain step. The arrows each from one to another part indicate the progress sequence of the steps. (D) part further includes (D1) part and (D2) part.

A mounting method of this embodiment includes: a stacking step PC1 of stacking an adhesive layer AL containing swell grains SG that swell when heat HT as predetermined energy is applied, on a projection-formed. surface WF1 of a semiconductor wafer (hereinafter, also referred to simply as “wafer”) WF as a work, the projection-formed surface WF1 having bumps BP as projections formed thereon; a mounting step PC4 of bringing the bumps BP into contact with a lead frame LF as a support to attach, to the lead frame LF, the wafer WF on which the adhesive layer AL is stacked; and an energy applying step PC5 of applying the heat HT to the adhesive layer AL to swell the swell grains SG, thereby making contact regions of the adhesive layer AL with the lead frame LF larger than before swelling the swell grains SG.

Note that this embodiment includes, between the stacking step PC1 and the mounting step PC4, a removing step PC2 of removing a foreign substance adhering to contact portions BP1, of the bumps BP, that are to be in contact with the lead frame LF, and further includes, on a preceding stage of the mounting step PC4, a dividing step PC3 of dividing the wafer WF into pieces to form chips CP as discrete pieces. Further, the thickness of the adhesive layer AL is set equal to or less than the height of the bumps BP.

As illustrated in (A) part of FIG. 1, the stacking step PC1 is a step of rolling a press roller 11 (press unit) on the adhesive layer AL and pressing the adhesive layer AL against the bumps BP and the projection-formed surface WF1 to paste the adhesive layer AL. The stacking step PC1 is capable of pasting the adhesive layer AL on the wafer WF by relatively moving the rolling press roller 11 and the wafer WF, that is, by moving one of the rolling press roller 11 and the wafer WF while restricting the movement of the other or by moving both.

At the end of the stacking step PC1, the bumps BP stick in the adhesive layer AL owing to the pressing of the press roller 11 and the contact portions BP1 are exposed from the adhesive layer AL, or the adhesive layer AL turns into a thin film to cover the contact portions BP1.

As illustrated in (B) part of FIG. 1, the removing step PC2 is a step of rotating a rotary brush 21 (removing unit) and bringing the rotating rotary brush 21 into contact with the contact portions BP1 to remove the adhesive layer AL, as the foreign substance, which is, for example, in the thin film state to cover the tops of the contact portions BP1. The removing step PC2 is capable of removing the foreign substance from the contact portions BP1 by relatively moving the rotating rotary brush 21 and the wafer WF, that is, by moving one of the rotating rotary brush 21 and the wafer WF while restricting the movement of the other or by moving both.

As illustrated in (C) part of FIG. 1, the dividing step PC3 is a step of rotating a rotary blade 31 (cutting unit) and moving the rotating rotary blade 31 along preset cutting lines of the wafer WF to divide the wafer WF into pieces, thereby forming the chips CP. The dividing step PC3 is capable of dividing the wafer WF into pieces by relatively moving the rotating rotary blade 31 and the wafer WF, that is, by moving one of the rotating rotary blade 31 and the wafer WF while restricting the movement of the other or by moving both.

The mounting step PC4 is a step of attaching, to the lead frame LF, the chip CP on which the adhesive layer AL is stacked. Specifically, as illustrated in (D) part of FIG. 1, the mounting step PC4 is a step of suction-holding the chip CP with a holding plate 41 (holding unit), bringing the contact portions BP1 of the suction-held chip CP into contact with predetermined positions of the lead frame LF, and thereafter vibrating the chip CP with a not-illustrated ultrasonic vibrating unit to bond the chip CP by ultrasonic bonding. Consequently, the chip CP is attached to a predetermined position of the lead frame LF only by projection bonding through the bumps BP.

Note that, in this embodiment, on a stage preceding the application of the heat HT to the adhesive layer AL in the energy applying step PC5, the adhesive layer AL is in a non-contact state (see (D) part of FIG. 1) in which the adhesive layer AL is not in contact with the lead frame LF or in a majority non-contact state in which the adhesive layer AL is partly in contact with the lead frame LF (see (D1) part and (D2) part of FIG. 1).

Here, the majority non-contact state refers to a state in which, in the adhesive layer AL stacked on the chip CP and exposed to the lead frame LF side, its initial contact regions in contact with the lead frame LF occupy less than 50% of its entire region.

As illustrated in (E) part of FIG. 1, the energy applying step PC5 is a step of making a coil heater 51 (heating unit) radiate the heat HT and applying the heat HT to the adhesive layer AL to swell the swell grains SG. Consequently, the adhesive layer AL abuts on the lead frame LF owing to the swelling of the swell grains SG contained in the adhesive layer AL, so that its contact regions become larger than before the swell grains SG swell. As a result, the chip CP attached to the lead frame LF only by the projection bonding or by the projection bonding and in the majority non-contact state adheres to the lead frame LF also through most part of the adhesive layer AL.

According to the embodiment described above, it is possible to prevent a lack of the adhesion of the chip CP to the lead frame LF since the contact regions of the adhesive layer AL with the lead frame LF enlarge owing to the swelling of the swell grains SG.

The invention is by no means limited to the above units and processes as long as the above operations, functions, or processes of the units and processes are achievable, still less to the above merely exemplary structures and processes described in the exemplary embodiment. For instance, the mounting step may be any mounting step within the technical scope of the invention in light of the common general technical knowledge at the time of the filing of the application as long as it is a step of bringing a projection into contact with a support to attach, to the support, a work on which an adhesive layer is stacked (the same applies to other units and steps).

An example of another adoptable configuration is such that a release liner RL as another sheet is temporarily bonded to one surface AL1 of the adhesive layer AL, the stacking step PC1 brings the other surface AL2 of the adhesive layer AL into contact with the projection-formed surface WF1 to stack the adhesive layer AL on the projection-formed surface WF1, and on a preceding stage of the mounting step PC4, a releasing step PC6 of releasing the release liner RL from the wafer WF on which the adhesive layer AL is stacked is executed.

Specifically, in the stacking step PC1, the press roller 11 presses the adhesive layer AL against the projection-formed surface WF1 of the wafer WF through the release liner RL to paste the adhesive layer AL as illustrated in (F) part of FIG. 1, and then the releasing step PC6 is executed.

In the releasing step PC6, a suction-holding member 61 (holding unit) may suction-hold the release liner RL to release the release liner RL from the adhesive layer AL as illustrated in (G) part of FIG. 1. This releasing step is capable of releasing the release liner RL from the adhesive layer AL by relatively moving the suction-holding member 61 suction-holding the release liner RL and the wafer WF, that is, by moving one of the suction-holding member 61 suction-holding the release liner RL and the wafer WF while restricting the movement of the other or by moving both.

In the stacking step PC1, the adhesive layer AL may be pasted on the projection-formed surface WF1 by a pasting device that suction-holds the adhesive layer AL with its holding member supported by an output shaft of a direct-acting motor (drive device) and enabled to hold the adhesive layer AL by a pressure-reducing unit such as a pressure-reducing pump or a vacuum ejector and presses the adhesive layer AL held by the holding member against the projection-formed surface WF1 to paste it, or the adhesive layer AL may be pasted on the projection-formed surface WF1 by a known pasting device or manually.

The removing step PC2 may be executed, for example, on a later stage of the dividing step PC3 and may be executed on any stage between the stacking step PC1 and the mounting step PC4. For example, in the removing step PC2, the foreign substance may be removed from the contact portions BP1 by plasma processing, by a removing device that removes the foreign substance from the contact portions BP1 by applying hot air or a cleaning liquid, by a known removing device, or manually. Examples of the removing unit other than the above-mentioned ones include those using sandpaper or gas spraying. The mounting method of the present invention may be one not including the removing step PC2.

Examples of the foreign substance removed from the contact portions BP1 include, other than the adhesive layer AL, stain and dust adhering to the contact portions BP1.

The dividing step PC3 may be executed on any stage preceding the mounting step PC4. For example, it may be executed on a preceding stage of the stacking step PC1, may be executed between the stacking step PC1 and the removing step PC2, or in the case where the removing step PC2 is not executed, may be executed between the stacking step PC1 and the mounting step PC4. For example, in the dividing step PC3, the wafer WF may be divided into pieces by a dividing device that, for example, makes a laser irradiator as a modified part forming unit emit laser light, moves the laser irradiator emitting the laser light along the preset cutting lines of the wafer WF to form modified parts in the wafer WF, and applies external force such as tension or vibration to the wafer WF in which the modified parts are formed, to form the chips CP, or the wafer WF may be divided into pieces by a known dividing device or manually. The mounting method of the present invention may be one not including the dividing step PC3.

In the case where the dividing step PC3 is the step of forming the chips CP by forming the modified parts in the wafer WF, the dividing step PC3 may include an external force applying step of applying the external force to the wafer WF in which the modified parts are formed, to form cracks starting from modified parts.

To form the modified parts, the modified part forming unit may embrittle, pulverize, liquefy, or hollow the wafer WF by changing the characteristics, properties, nature, material, composition, structure, size, or the like of the wafer WF by applying, other than the laser light, an electromagnetic wave, vibration, heat, chemicals, a chemical substance, or the like. Such modified parts may be any as long as they make it possible to divide the work into pieces to form the discrete pieces.

The dividing step PC3 may divide the wafer WF into two or into three or more. The chip CP formed as a result of the dividing may be in any shape such as a circular shape, an elliptical shape, a polygonal shape such as a triangular shape, a quadrangular shape, or a more sided polygonal shape.

In the mounting step PC4, the chip CP may be attached to the lead frame LF by a mounting device that grips the chip CP with its chuck cylinder (drive device) and brings the contact portions BPI of the chip CP gripped by the chuck cylinder into contact with the predetermined positions of the lead frame LF to attach the chip CP, or the chip CP may be attached to the lead frame LF by a known mounting device or manually. The mounting step PC4 does not necessarily have to bring the adhesive layer AL into the non-contact state or the majority non-contact state with the lead frame LF, and for example, on a stage preceding the application of the heat HT to the adhesive layer AL in the energy applying step PC5, the percentage of the initial contact regions may be 50% or more, for example, 51%, 75%, or 99%. What is important is that the contact regions of the adhesive layer AL with the lead frame LF can be made larger when the swell grains SG swell in the energy applying step PC5 than before the swell grains SG are swollen.

A method of the bonding process executed in the mounting step PC4 may be any, and for example, it may be bonding using an adhesive (tackiness agent), an adhesive (tacky) sheet, or an adhesive (tacky) tape, or may be bonding by melting, baking, soldering, or the like.

In the energy applying step PC5, the swell grains SG may be swollen by an energy applying device that makes its infrared heater emit the heat HT and applies the heat HT to the adhesive layer AL to swell the swell grains SG, or the heat HT may be applied to the adhesive layer AL by a known energy applying device or manually to swell the swell grains SG. The heating unit may be, for example, a heating side of a heat pipe, a water heater, or the like other than the above-mentioned ones.

The energy applying step PCS may apply the heat HT to the whole adhesive layer AL at a time or may apply the heat HT to part of the adhesive layer AL. In the energy applying step PC5, the duration of the application of the heat HT to the adhesive layer AL may be optionally decided in consideration of the characteristics, properties, nature, material, composition, structure, and so on of the swell grains SG. The application of the heat HT may be performed step by step from one end toward the other end of the wafer WF or the chip CP. The heat HT may be applied to the adhesive layer AL from any position, for example, from the wafer WF or chip CP side to the adhesive layer AL, from the lead frame LF side to the adhesive layer AL, from the lateral side of the wafer WF or chip CP or the lead frame LF to the adhesive layer AL.

The energy applying step PC5 may be executed in the mounting step PC4. A configuration example in this case may be such that a heating unit provided in the holding plate 41 is driven when the wafer WF on which the adhesive layer AL is stacked is attached to the lead frame LF in the mounting step PC4 (at this time, the bonding process may be executed or does not necessarily have to be executed), to apply the heat HT to the adhesive layer AL to swell the swell grains SG, thereby enlarging the contact regions of the adhesive layer AL with the lead frame LF.

The releasing step PC6 may be executed between the dividing step PC3 and the mounting step PC4 in the case where the removing step PC2 is not executed. In this case, the dividing step PC3 divides the wafer WF on which the adhesive layer AL with the release liner RL is stacked, into pieces by the rotary blade 31. The releasing step PC6 may be executed on any stage preceding the mounting step PC4.

Further, in the releasing step PC6, the release liner RL may be released from the adhesive layer AL by a releasing device that grips a band-shaped or sheet-by-sheet-type release tape, which is pasted on the release liner RL, with its chuck cylinder (drive device) and releases the release liner RL from the adhesive layer AL by relatively moving the chuck cylinder and the wafer WF, or the release liner RL may be released from the adhesive layer AL by a known method or manually.

The other sheet to be released in the releasing step PC6 may be an adhesive sheet in which a predetermined adhesive layer is stacked on a predetermined base, a cover sheet protecting the adhesive layer AL, or the like.

The swell grains SG contained in the adhesive layer AL may be those that are swollen by any energy, for example, an electromagnetic wave such as ultraviolet rays, visible rays, an acoustic wave, X rays, or gamma rays, heat of hot water, hot air, or the like, and the predetermined energy in the energy applying step PC5 may be any energy, for example, an electromagnetic wave such as ultraviolet rays, visible rays, an acoustic wave, X rays, or gamma rays, heat of hot water, hot air, or the like, depending on the characteristics, properties, nature, material, composition, structure, and so on of the swell grains SG, and the predetermined energy may be any as long as it can swell the swell grains SG to make the contact regions of the adhesive layer AL with the support larger than before the swell grains SG swell.

As the swell grains SG, grains each having an elastic shell encapsulating a substance, such as isobutane, propane, or pentane, that is easily gasified to swell by heat can be exemplified, and examples of the swell grains SG include, but are not limited to, the thermally foamable grains disclosed in Japanese Patent Application No. 2017-73236, Japanese Patent Application Laid-open No. 2013-159743, Japanese Patent Application Laid-open No. 2012-167151, Japanese Patent Application Laid-open No. 2001-123002, and so on which are explicitly incorporated in the present specification by reference and swell grains disclosed in Japanese Patent Application Laid-open No. 2013-47321, Japanese Patent Application Laid-open No. 2007-254580, Japanese Patent Application Laid-open No. 2011-212528, Japanese Patent Application Laid-open No. 2003-261842, and so on which are explicitly incorporated in the present specification by reference.

For example, a foaming agent that generates water, carbonic acid gas, or nitrogen through pyrolysis to exhibit a similar effect to that of the swell grains may be adopted. Also adoptable are those whose shells are swollen by a gas generating agent such as an azo compound which generates gas when exposed to ultraviolet rays, as disclosed in Japanese Patent Application Laid-open No. 2016-53115 and Japanese Patent Application Laid-open No. H07-278333 which are explicitly incorporated in the present specification by reference, or for example, those that are swollen by heating, such as rubber or resin, or baking soda, sodium acid carbonate, baking powder, or the like.

In the mounting method of the present invention, a polishing (grinding) step of polishing (grinding) the wafer WF or the chip CP to a predetermined thickness may be executed on a preceding stage, a later stage, or the like of the stacking step PC1, the removing step PC2, the dividing step PC3, the mounting step PC4, the energy applying step PC5, or the releasing step PC6.

The adhesive layer AL may be of a pressure-sensitive bonding type or a heat-sensitive bonding type. If the adhesive layer AL is of the heat-sensitive bonding type, it may be bonded by an appropriate method, for example, by an appropriate heating unit for heating the adhesive layer AL, such as a coil heater or a heating side of a heat pipe. Further, the adhesive layer AL may be, for example, a single-layer one having only the adhesive layer, a double-faced adhesive type having one intermediate layer or more, or a single-layer or a multilayer one not having an intermediate layer. The adhesive layer AL may have a circular shape, an elliptical shape, a polygonal shape such as a triangular shape or a quadrangular shape, or any other shape. In the case where the adhesive layer AL has the intermediate layer, the swell grains SG may be added only to the adhesive layer AL, only to the intermediate layer, or to both of the adhesive layer AL and the intermediate layer.

The work and the support each may be, for example, a single item such as food, a resin container, a semiconductor wafer such as a silicon semiconductor wafer or a compound semiconductor wafer, a circuit board, an information recording substrate such as an optical disk, a glass plate, a glass instrument, a steel sheet, a metal product, pottery, a wood board, a wood product, or a resin, or may be a composite made up of two of these and more. The work and the support each may also be a member, an article, or the like of any form, and the material, type, shape, and so on thereof are not limited. A projection formed on such a work may be any, for example, may be a fastening member such as a bolt or a nut, or may be a resin-molded protrusion. The shape of the work, the support, and the projection may be, for example, a circular shape, an elliptical shape, a polygonal shape such as a triangular shape or a quadrangular shape, a cubic shape, a rectangular parallelepiped shape, a spherical shape, a circular cylindrical shape, a prismatic shape, a circular conical shape, a pyramid shape, or any other shape.

The drive device in the above-described embodiment may be an electric machine such as a rotary motor, a direct-acting motor, a linear motor, a uniaxial robot, or a multi joint robot having two joints or three or more joints, an actuator such as an air cylinder, a hydraulic cylinder, a rodless cylinder, or a rotary cylinder, or the like, or may be one in which some of these are directly or indirectly combined.

In the above-described embodiment, in a case where a rotating member such as a roller is used, a drive device that drives the rotation of the rotating member may he provided, and the surface of the rotating member or the rotating member itself may be formed of a deformable member such as rubber or resin, or may be formed of a non-deformable member. Instead of the roller, another member such as a shaft or a blade that rotates or does not rotate may be adopted, In a case where a presser, such as a press unit or a press member such as a press roller or a press head, that presses an object to be pressed is adopted, a member such as a roller, a round bar, a blade member, rubber, resin, or sponge may be adopted or a structure that sprays gaseous substance such as the atmospheric air or gas for pressing may be adopted, instead of or in addition to those exemplified in the above, and the presser may be formed of a deformable member such as rubber or resin or may be formed of a non-deformable member. In a case where a member, such as a support (holding) unit or a support (holding) member, that supports or holds a member to be supported is adopted, the member to be supported may be supported (held) by a gripping unit such as a mechanical chuck or a chuck cylinder, Coulomb force, an adhesive (adhesive sheet, adhesive tape), a tackiness agent (tacky sheet, tacky tape), magnetic force, Bernoulli adsorption, suction/adsorption, a drive device, or the like. In a case where one such as a cutting unit or a cutting member, that cuts a member to be cut or forms an incision or a cutting line in a member to be cut is adopted, one that cuts with a cutter blade, a laser cutter, ion beams, thermal power, heat, water pressure, a heating wire, or the spraying of gas, liquid, or the like may be adopted instead of or in addition to those exemplified above. Further, an appropriate combination of drive devices may move one that cuts the object to be cut at the time of the cutting

What is claimed is:

1. A mounting method comprising:
a stacking step of stacking an adhesive layer containing a swell grain that swells when predetermined energy is applied, on a projection-formed surface of a work, the projection-formed surface having a projection formed thereon;
a mounting step of bringing the projection into contact with a support to attach, to the support, the work on which the adhesive layer is stacked; and
an energy applying step of applying the energy to the adhesive layer to swell the swell grain, thereby making a contact region of the adhesive layer with the support larger than before swelling the swell grain.

2. The method of claim 1,
wherein a thickness of the adhesive layer is set equal to or less than a height of the projection, and on a stage preceding the application of the energy to the adhesive layer in the energy applying step, the adhesive layer is in a non-contact state in which the adhesive layer is not in contact with the support or in a majority non-contact state in which the adhesive layer is partly in contact with the support.

3. The method of claim 1, further comprising, between the stacking step and the mounting step,
a removing step of removing a foreign substance adhering to a contact portion, of the projection, that is to be in contact with the support.

4. The method of claim 1, further comprising, on a preceding stage of the mounting step,
a dividing step of dividing the work into pieces to form a discrete piece,
wherein the mounting step attaches, to the support, the discrete piece on which the adhesive layer is stacked.

5. The method of claim 1,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

6. The method of claim 2, further comprising, between the stacking step and the mounting step,
a removing step of removing a foreign substance adhering to a contact portion, of the projection, that is to be in contact with the support.

7. The method of claim 2, further comprising, on a preceding stage of the mounting step,
a dividing step of dividing the work into pieces to form a discrete piece,
wherein the mounting step attaches, to the support, the discrete piece on which the adhesive layer is stacked.

8. The method of claim 2,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

9. The method of claim 3, further comprising, on a preceding stage of the mounting step,
a dividing step of dividing the work into pieces to form a discrete piece,
wherein the mounting step attaches, to the support, the discrete piece on which the adhesive layer is stacked.

10. The method of claim 3,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

11. The method of claim 4,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

12. The method of claim 6, further comprising, on a preceding stage of the mounting step,
a dividing step of dividing the work into pieces to form a discrete piece,
wherein the mounting step attaches, to the support, the discrete piece on which the adhesive layer is stacked.

13. The method of claim 6,
wherein another sheet is to temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

14. The method of claim 7,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

15. The method of claim 9,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.

16. The method of claim 12,
wherein another sheet is temporarily bonded to one surface of the adhesive layer, and
wherein the stacking step brings another surface of the adhesive layer into contact with the projection-formed surface to stack the adhesive layer on the projection-formed surface,
the method further comprising, on a preceding stage of the mounting step, a releasing step of releasing the other sheet from the work on which the adhesive layer is stacked.
